(19) United States
(12) Patent Application Publication
(10) Pub. No.: US 2004/0224482 A1
(43) Pub. Date: Nov. 11, 2004

(54) Method for transferring thin film layer material to a flexible substrate using a hydrogen ion splitting technique

(76) Inventors: Francis J. Kub, Arnold, MD (US); Karl D. Hobart, Upper Marlboro, MD (US)

Correspondence Address: NAVAL RESEARCH LABORATORY, ASSOCIATE COUNSEL (PATENTS), CODE 1008.2, 4555 OVERLOOK AVENUE, S.W., WASHINGTON, DC, 20375-5320, US

(21) Appl. No.: 10/022,364

(22) Filed: Dec. 20, 2001

(51) Int. Cl. H01L 21/30; H01L 21/46

(52) U.S. Cl. 438/458; 438/459

(57) ABSTRACT

A method for making thin film functional material and thin film single crystal semiconductor devices having a flexible substrate is provided. In one alternative, a film layer of thin film functional material is grown on a large diameter growth substrate. One or more protective layer may be deposited on the surface of the growth substrate before the thin film functional material is deposited. Hydrogen is implanted to a selected depth within the growth substrate [or within a protective layer] to form a hydrogen ion layer. The growth substrate and associated layers are bonded to a second substrate. The layers are split along the hydrogen ion implant and the portion of the growth substrate and associated layers, which is on the side of the ion layer away from the second substrate, is removed. In another alternative, an implanted single crystal semiconductor substrate material is bonded to a flexible substrate. The substrate is split and a thin film of the single crystal semiconductor material remains bonded to the flexible substrate.

### BACKGROUND OF THE INVENTION

1. Field of the Invention

The present invention relates to the manufacture of layered flexible semiconductor materials, and more particularly, the invention relates to a method for manufacturing a functional flexible semiconductor by transferring a single-crystal semiconductor material or thin film material to a flexible substrate.

2. Related Art

There is interest within the art in cost-effective ways to improve the manufacture of devices having thin film functional materials and thin film single crystal semiconductor materials bonded on a flexible substrate; a flexible substrate being a material understood to have flexibility in excess of that of silicon. Flexible substrates offer the advantages of low weight, high flexibility and relative strength. Semiconductor devices with flexible substrates are often made by placing thin film functional materials or single layer semiconductor materials over a suitable flexible substrate.

A common approach of making thin film transistors on flexible substrates is to deposit a thin amorphous silicon layer at a low temperature on either a Kapton substrate or a stainless steel flexible substrate and then heat the thin amorphous silicon using a laser to recrystallize the amorphous silicon to form polysilicon grains of silicon. Thin film transistors are then fabricated in this thin film amorphous or polysilicon material with laser heating used to activate implant dopant for source and drain.

The thin film functional materials are typically high temperature superconducting (YBCO), ferroelectric, piezoelectric, pyroelectric, high dielectric constant, electro-optic, photoreactive, waveguide, non-linear optical, superconducting, photodetecting, solar cell, semiconductor, wideband gap semiconductor, shaped memory alloy, electrically conducting, or have other desired qualities.

Additionally, there is much application within the art for single crystal semiconductor materials with flexible substrates. The thin film semiconductor material with flexible substrates can be used for such devices as flexible and low weight transmissive displays, reflective displays, emissive displays, metal tape used for shielding, smart aperture antennae, solar cells, retina prosthesis, MEMs, sensors and actuators, and flexible single-crystal semiconductor optical waveguides.

To obtain a high quality thin film functional material, the thin layer is typically grown at a growth temperature or annealing temperature of 500 C.-100 C. The high growth temperature is required to assure a high quality thin film material. However, the highest temperature that a flexible substrate material can withstand is about 150 C. Therefore, it is generally not possible to obtain the best quality thin film material by growing the material directly on a flexible substrate.

An optimal solution is to grow the thin film functional material on a first, or growth, substrate, such as silicon, that can withstand the increased temperatures and then transfer the thin film material after it is grown to the flexible substrate. However, there have been problems with isolating, and then transferring, the thin film layer. If the growth substrate is etched away, mechanically lapped forced, or eliminated from the thin film layer in similar fashion, the risk of damage to the thin film layer during this process is considerable. Further, some growth substrate materials are very expensive, and elimination of the substrate to isolate the thin film layer is cost prohibitive. Once the thin film layer is separated from the growth substrate, there is a second problem. The thin film functional layer must have a smooth surface for the transition and bonding to the second substrate to be successful. Otherwise, the bond to the flexible substrate may not hold properly, and the device will not function optimally.

It is also not possible to grow a thin film layer of single crystal semiconductor material directly on a flexible substrate. This is because there is no lattice to initiate the single crystal growth. Once again, the ideal solution is to grow a layer of the thin film single crystal material and transfer it to the flexible substrate. Like the functional material layer, the single crystal semiconductor material layer must have a smooth surface for the transition and bonding to the flexible substrate to be successful.

There have been attempts in the prior art to address these issues. Prior art of interest includes. U.S. Pat. No. 6,054,370 to Doyle; U.S. Pat. No. 6,020,252 to Aspar et al.; U.S. Pat. No. 6,010,579 to Henley et al.; U.S. Pat. No. 5,994,207 to Henley et al.; U.S. Pat. No. 5,993,677 to Biasse et al.; U.S. Pat. No. 5,966,620 to Sakaguchi et al.; U.S. Pat. No. 5,877,070 to Goesele et al.; U.S. Pat. No. 5,882,987 to Srikrishnan; U.S. Pat. No. 5,985,688 to Bruel; U.S. Pat. No. 5,714,395 to Bruel; U.S. Pat. No. 5,374,564 to Bruel; U.S. Pat. No. 5,654,583 to Okuno et al.; and U.S. Pat. No. 5,391,257 to Sullivan et al.

The Doyle, Aspar et al ('252), Henley et al. ('207), Biasse, Sakaguchi et al., and Goesele et al. patents each disclose methods which utilize, to some extent, ion implantation, wafer bonding, and layer splitting for the transfer of semiconductor films to second substrates. For example, the Biasse et al. patent discloses a method for transferring a thin film from an initial substrate to a final substrate by joining the thin film to a handle substrate, cleaving the initial substrate, joining the thin film to a final substrate, and cleaving the handle substrate. The Goesele et al. patent discloses a method of transferring thin monocrystalline layers to second substrates at lower temperatures than previously possible.

The Bruel ('688) patent discloses a method for inserting a gaseous phase in a sealed cavity by ion implantation. The Bruel ('395) patent discloses a method for making thin monocrystalline films. The Bruel ('564) patent discloses a hydrogen ion implant splitting method that involves combining wafer bonding with a hydrogen implantation and separation technique. The hydrogen implantation and separation technique utilizes a heavy dose of implanted hydrogen together with subsequent annealing to produce H exfoliation that releases the host substrate to generate the SOI structure. The surface following exfoliation has a microroughness of about 8 nm, and must be given a slight chemomechanical polish to produce a prime surface. The Henley et al. ('579) patent discloses a method for the manufacture and reuse of substrates. The Srikrishnan patent discloses a method for the production of monocrystalline films using an etch stop layer. The Okuno et al. patent discloses a method for direct bonding different semiconductor structures in order to form a unified semiconductor device. The Sullivan et al. patent discloses a method for transferring thin films, which utilizes etch stop layers.

Hobart et al. al, describes an approach of implementing ultrathin semiconductor layers wafer bonded to a substrate by using a process of hydrogen implantation or hydrogen implant in combination with other elements to a selected depth into a wafer with that contains one or more semiconductor etch stops layers, treatment to cause the wafer to split at the selected depth, and subsequent etching procedures to expose etch stop layer and ultra-thin semiconductor layer.

It has been found experimentally that there are a number of techniques to either reduce the required hydrogen ion implantation dose or to reduce the temperature needed to cause hydrogen ion implantation substrate layer splitting process to work. One technique involves the use of a high pressure nitrogen gas steam or liquid directed towards the side of a silicon substrate into which a high dose hydrogen ion implantation has been made. It has been experimentally found that the hydrogen ion implantation substrate layer splitting process can occur at room temperature for the case of a silicon substrate into which a high hydrogen ion implantation dose has been made using the high pressure nitrogen gas stream method. It has also been found experimentally that a helium ion implantation made in combination with a hydrogen ion implantation can be used to achieve a lower total implanted dose for the substrate layer splitting process to occur for a given anneal temperature. It has also been found experimentally that a lower substrate layer splitting temperature is achieved for the case that a hydrogen ion implantation is made into a silicon substrate having a high boron concentration. The high boron concentration can be incorporated into a silicon substrate by ion implantation. The lower temperature for hydrogen ion implantation substrate layer splitting to occur is obtained both for the case that the boron implant is annealed and for the case that the boron implant is unannealed.

However, these prior art references fail to describe an approach of transferring a thin film to a flexible substrate and a transfer process that is compatible with the low temperature requirements of a flexible substrate.

### SUMMARY OF THE INVENTION

A method is disclosed for transferring thin film materials to a flexible substrate. In one embodiment, the method comprises the steps of: implanting hydrogen or hydrogen in combination with other elements to a selected depth within a single crystal semiconductor material substrate which optionally can contain etch stop layers; optionally depositing a stiffening material layer 17 on the surface of the single crystal substrate; bonding the surface of the single crystal semiconducting material substrate or surface of the stiffening layer to a flexible substrate; and performing a treatment to cause the single-crystal substrate to split at the selected depth so that the portion of the single crystal substrate which is on the side of the implant layer away from the flexible substrate is removed, wherein a remaining thin film portion is attached to the flexible substrate, and if an etch stop layer is incorporated in the single crystal semiconductor substrate etching to the stop layer and then removing the etch stop layer by etching.

Preferably, the single crystal semiconductor substrate further comprises a material selected from a group consisting of silicon, germanium, InP, and GaAs. Advantageously, the flexible substrate comprises a material selected from a group consisting of stainless steel foil, plastic, polyimide, polyester, and mylar.

Preferably, the optional stiffening material layer consist of low temperature deposited silicon oxide, silicon nitride, silicon, SiC, AlN, diamond, spin on glass, metal, polyimide, polymer, glass, frit, or solder.

Optionally, a high pressure nitrogen gas steam or liquid stream is directed towards the side of a single crystal substrate into which a high dose hydrogen ion implantation has been made to split the single crystal substrate at the selected depth.

Optionally, boron is implanted at the same selected depth as the implanted hydrogen for lowering the thermal energy required to split the single crystal substrate. Advantageously, an adhesive layer is provided between the bonding surfaces of the thin film functional layer and the flexible substrate before or during the bonding step for improving the bonding thereof.

Optionally, the surface of the split silicon layer is smoothed using technique of chemical mechanical polishing, chemical etching, sputtering, chemical oxidation and etch, ion milling, or chemical etching to an etch stop layer such as SiGe or boron doped silicon that resides within the thin film layer.

A thin film transistor is fabricated in the thin film layer.

In another embodiment, the method comprises the steps of: depositing an optional protective layer on one surface of a large diameter growth substrate; growing a thin film layer of thin film functional material on the optional protective layer, the functional material comprising a material selected from the group consisting of high temperature superconducting (YBCO), ferroelectric, piezoelectric, pyroelectric, high dielectric constant, electro-optic, photoreactive, waveguide, non-linear optical, superconducting, semiconducting, photodetecting, solarcell, wideband gap, shaped memory alloy, and electrically conducting materials; implanting hydrogen or hydrogen in combination with other elements to a selected depth within the growth substrate or within the at least one protective layer to form a hydrogen ion layer so as to divide the material having the growth substrate and the optional protective layer into distinct portions; optionally deposit a stiffening layer on the growth substrate, bonding the growth substrate including the optional protective layer and the functional thin film layer to a second flexible substrate; splitting the material having the growth substrate and optional protective layer along the implanted ion layer and removing the portion of the material which is on the side of the ion layer away from the flexible substrate.

Preferably, the growth substrate is comprised of a material selected from a group consisting of silicon, germanium, InP, GaAs, quartz, and sapphire, and advantageously, the growth substrate comprises silicon.

Advantageously, the growth substrate comprising silicon; the optional protective layer comprises an oxide layer, an adhesion layer, and a barrier layer; and the oxide layer is deposited on the silicon substrate; the adhesion layer is deposited on the oxide layer; and the barrier layer is deposited on the adhesion layer for isolating the thin film layer. Preferably, the adhesion layer is comprised of titanium, and the barrier layer comprises a material selected from a group consisting of platinum and iridium.

Preferably, the at least one protective layer comprises MgO.

Advantageously, the thin film functional material is comprised of a material selected from a group consisting of a single crystal material, a polycrystalline material, and a high temperature sinter ceramic material.

Preferably, the flexible substrate further comprises a material selected from a group consisting of stainless steel foil, plastic, polyinide, polyester, and Mylar.

Optionally, the thin film functional material layer is annealed for strengthening and tempering the thin film layer.

Preferably, the optional stiffening material layer consist of low temperature deposited silicon oxide, silicon nitride, silicon, SiC, AlN, diamond, spin on glass, metal, polyimide, polymer, glass, frit, and solder.

Optionally, a high pressure nitrogen gas steam or liquid stream is directed towards the side of a single crystal substrate into which a high dose hydrogen ion implantation has been made to split the single crystal substrate.

Optionally, boron is implanted at the same selected depth as the implanted hydrogen for lowering the thermal energy required to split the single crystal growth substrate.

Preferably, an adhesive layer is provided between the bonding surfaces of the thin film functional layer and the flexible substrate before or during the bonding step for improving the bonding thereof.

In yet another embodiment, the film layer of thin film functional material is grown directly on the surface of the growth substrate and the hydrogen is implanted within the growth substrate.

Other features and advantages of the invention will be set forth in, or will be apparent from, the detailed description of preferred embodiments of the invention, which follows.

### BRIEF DESCRIPTION OF THE DRAWINGS

FIG. 1a is a schematic side elevational view illustrating a step in a first preferred embodiment of the method of the invention.

FIG. 1b is a schematic side elevational view of a finished product resulting from the method of the embodiment of FIG. 1a.

FIG. 2a is a schematic side elevational view illustrating a step in an embodiment of the method of the invention.

FIG. 2b is a schematic side elevational view of a finished product resulting from the method of the embodiment of FIG. 2a.

FIG. 3a is a schematic side elevational view illustrating a step in an embodiment of the method of the invention.

FIG. 3b is a schematic side elevational view of a finished product resulting from the method of the embodiment of FIG. 3a.

### PREFERRED EMBODIMENTS OF THE INVENTION

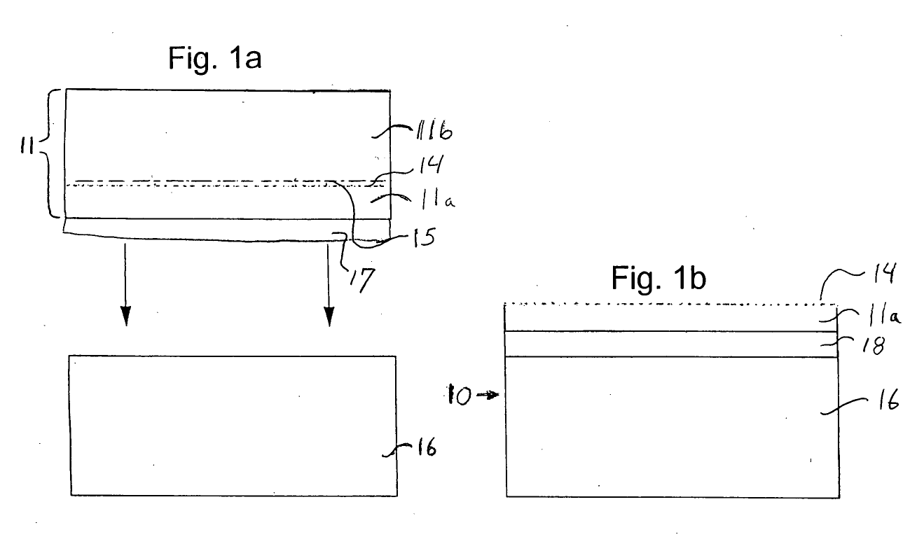

Preferred embodiments of the flexible substrate transfer method will be discussed with reference to the drawings Referring to FIG. 1a, the basic method of thin film layer transfer is illustrated. The fabrication process begins with a first substrate 11. In this embodiment, the first substrate is comprised of a single crystal semiconductor substrate. The single crystal semiconductor material is often silicon or GaAs.

A hydrogen ion implant operation is carried out next. A hydrogen ion splitting layer 14, i.e. the peak of the hydrogen implant, is implanted, within the single crystal semiconductor substrate 11. The first substrate is divided into portions 11a and 11b.

An optional stiffening material layer 17 is deposited on the surface of the single crystal substrate. The stiffening material is deposited at low temperature (below the splitting temperature for the hydrogen ion implanted layer) and can consist of deposited silicon oxide, silicon nitride, silicon, SiC, AlN, diamond, spin on glass, metal, polyimide, polymer, glass, frit, and solder. Several techniques of depositing the stiffening layer include sputtering, evaporation, chemical vapor deposition, spraying, and spin on glass.

The single crystal substrate 11 is bonded to a second flexible substrate 16 shown at the bottom of FIG. 1a. The flexible substrate 16 is typically comprised of stainless steel foil, plastic, polyimide, polyester, Mylar or other suitable flexible materials. A flexible substrate is understood to be a substrate having flexibility in excess of that of silicon.

There are numerous methods available for carrying out the layer bonding. These bonding methods include conductive polymer adhesive bonding, organic adhesive bonding, indium cold weld bonding, ultrasonic bonding, anodic bonding, reaction bonding, solder glass bonding, frit glass bonding, thermal compression bonding, vacuum bonding, epoxy bonding, silver colloid, graphite colloid, resist bonding, soft solder bonding, or other suitable bonding techniques. Because of limitations of the flexible substrate materials in withstanding heat, it is generally required that the technique used for bonding have a maximum temperature of approximately 150 C.-200 C. This temperature limitation is specifically true for many organic flexible substrates. However, stainless steel and polyamide substrates can withstand higher bond temperatures.

An optional adhesive layer 18 may be provided between the first substrate 11 and flexible substrate 12 if needed to provide effective bonding. Some bonding techniques such as ultrasonic bonding or laser bonding may not require the adhesive layer 18.

After the bonding step is completed, hydrogen layer splitting is carried out at the splitting layer or ion implant peak 14, resulting in the separation of substrate part 11b from the remainder of the first substrate 11a. Hydrogen layer splitting can be performed preferably by using one of two conventional methods. The first method involves heating. Such heating causes the hydrogen within the layer to expand and the expansion of the hydrogen layer 14 produced splitting of the substrate 11, and the separation of substrate portion 11b from the remainder of the substrate 11a. Hydrogen layer splitting can also be carried out by directing a high-pressure gas stream towards the side of the wafer at the location of the hydrogen ion implant layer 14. The substrate 11 splits under the pressure of the high-pressure gas stream or liquid stream from the side of the single crystal substrate at the location of the hydrogen implant peak or splitting layer 14. This splitting can be achieved even at room temperature. The high-pressure method thus can be used with polymer adhesives, which can typically be exposed to a maximum temperature of approximately 150° C. It is noted that there are other bonding materials which can withstand only a low temperature hydrogen layer splitting operation and thus can likewise be used with the high pressure gas initiated hydrogen implant layer splitting. These bonding materials include conductive polymer adhesives, silver paint, graphite paint, epoxy bonding material, soft solders, and indium cold welding material.

If heat is used to initiate the splitting, a lowered temperature for the splitting can be obtained by adding, in addition to the hydrogen implant layer 14, a boron implant layer 15 at the same location as the hydrogen implant layer 14. The boron layer 15, added to the hydrogen layer 14, decreases the splitting temperature of the layers. In FIG. 1a, the boron layer 15 is shown slightly apart from the hydrogen layer 14 for clarity. The lowest splitting temperature demonstrated for silicon is 200° C.-250° C. by using a combination of the hydrogen implant and the boron implant with the peak of both implants at the same location.

Referring to FIG. 1b, a product 10 resulting from the steps of this embodiment, which is ready for fabrication into a flexible substrate device, is shown.

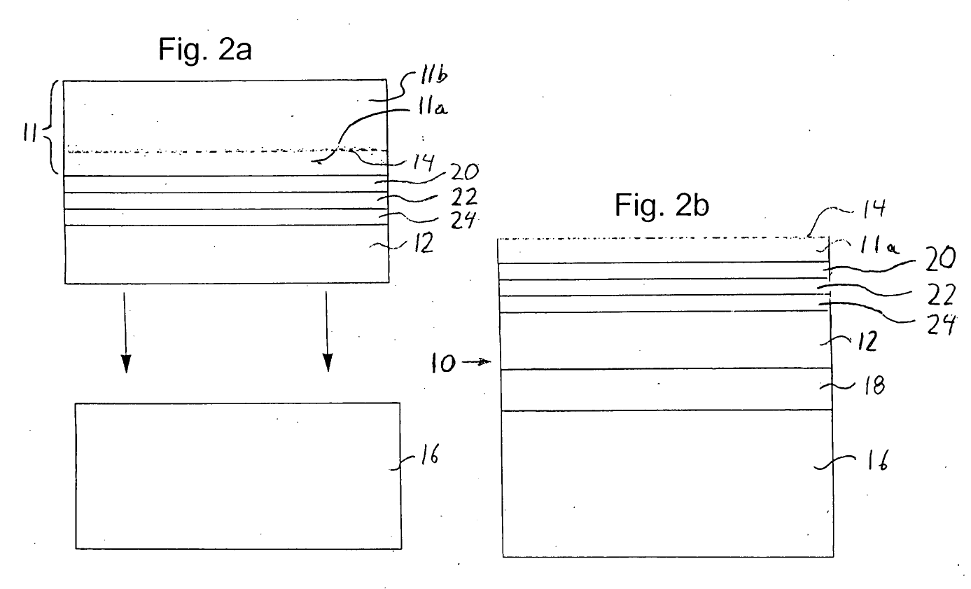

Turning to FIGS. 2a, there is shown an embodiment, which is a modification of the method described herein above. In the embodiments to follow, a thin film functional material layer 12 is grown and transferred to the flexible substrate 16. Because this embodiment and the remaining embodiments herein are similar to that of FIGS. 1a-1b, corresponding elements have been given the same reference numerals. In this embodiment, the first substrate 11 is a large diameter growth substrate, as the meaning of the term “large diameter” is understood within the art. Growth substrate materials include silicon, GaAs, quartz, sapphire, or other suitable growth substrate materials. In this embodiment, the growth substrate 11 is silicon. Of the potential growth substrate materials, the material of the most interest is silicon because large diameter silicon substrates can readily be obtained from silicon at low cost.

A thin film layer of functional material 12 is grown on the growth substrate 11. The material of the thin film functional layer 12 is often a polycrystalline material. In addition, the functional material can be a high temperature sinter ceramic material, or single-crystal materials such as SrTiO3, LiNbO3, and the like. The thin film layer 12 can be grown upon the growth substrate 11 using conventional methods known in the art such as sputter deposition, pulse laser deposition, solgel techniques, MOCVD, MBE, CVD, or other suitable methods. After being grown, the thin film layer 12 can be annealed for strengthening and tempering.

When silicon is used as the growth substrate material, and as indicated above, silicon is a preferred growth substrate material, some thin film materials such as SrBaTiO₃ and LiNbO₃ typically would not be grown directly on the silicon growth substrate 11 due to the detrimental effects of reactions between the thin film layer 12 with the silicon of grown substrate 11. In such cases, as typified in this embodiment, the thin film layer 12 is grown on a protective layer 24 located between the thin film layer 12 and growth substrate 16. Protective layer 24 preferably comprises a platinum layer or iridium layer.

An oxide layer 20 is grown on the silicon substrate 11. An adhesion layer 22, preferably titanium containing adhesion layer, is deposited on the oxide layer 20. The platinum or iridium layer 24 is deposited on the titanium adhesion layer 22. The oxide layer 20 insulates the silicon substrate 11, and the adhesion layer 22 facilitates bonding between the oxide layer 20 and the protective layer 24.

When a platinum or iridium protective layer 24 is present, the hydrogen implant will pass through the platinum or iridium film 24, the thin film layer 12 and other layers, with the peak of the dose residing in the silicon to create a hydrogen implant splitting layer 14 located within the growth substrate 11. The implant layer 14 is typically placed within the silicon substrate 11 to prevent damage to the protective layers or thin film layer 12 from splitting of the layer to be described herein.

The surface of the thin film layer 12 is bonded to the surface of the flexible substrate 16. As illustrated herein, an optional adhesive layer 18 may be provided between the bonding surfaces to facilitate the bonding process. If desirable, the remaining silicon material 11a and up to all the protective layers 20, 22, 24 can be etched away, so as to leave only the thin film functional layer 12, or the thin film functional layer 12 and the platinum layer 24, bonded to the flexible substrate 16.

In FIG. 2b, the product 10 resulting from the steps of the embodiment, which is ready for fabrication into a flexible substrate device, is shown.

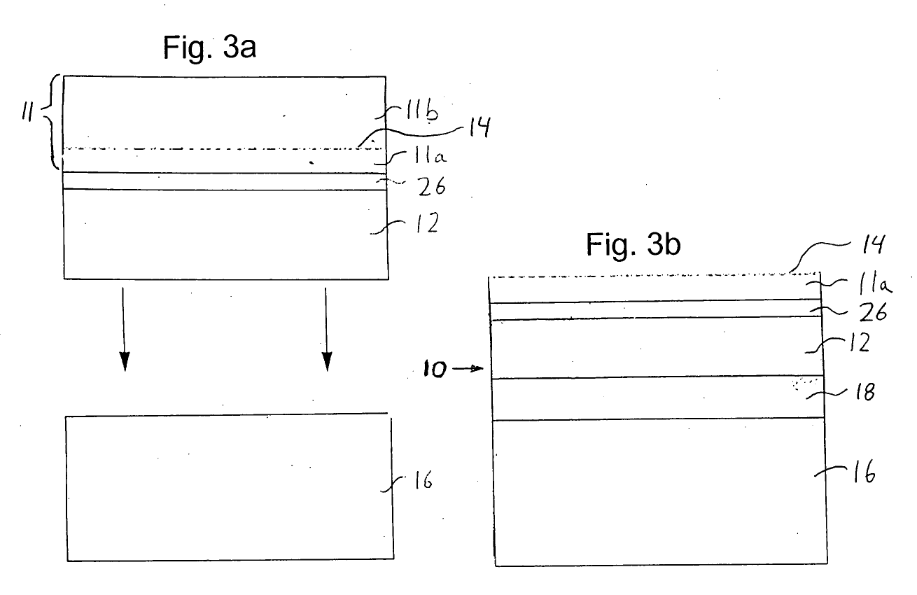

Turning to FIG. 3a, a further embodiment of the thin layer transfer method of FIGS. 1a-1b is shown. An MgO buffer layer 26 is deposited on the growth substrate 11, and the thin film layer 12 is deposited on the MgO layer 26. The MgO layer is used as a buffer layer instead of the platinum or iridium layer 24, adhesive layer 22 and oxide layer 20 shown in the alternative embodiment disclosed herein. If the MgO layer 26 is sufficiently thick, the hydrogen layer 14 can be implanted within the MgO layer 26 instead of the growth substrate 11. In this embodiment, the implant layer 14 is within the growth substrate 11.

Similar to the previous embodiment herein, the protective MgO layer 26 can be etched away, so as to leave only the thin film functional layer 12, bonded to the flexible substrate 16.

In FIG. 3b, the product 10 resulting from the steps of the embodiment, which is ready for fabrication into a flexible substrate device, is shown.

Although the invention has been described above in relation to a preferred embodiment thereof, it will be readily understood by those skilled in the art that variations and modifications can be effected without departing from the scope and spirit of the invention.

1: A method for making a thin film device, said method comprising the steps of:
(a) implanting hydrogen ions to a selected depth within a single crystal semiconducting material substrate having implant-damaged stiffening material on the single crystal substrate to form a hydrogen ion layer so as to divide the single crystal substrate into two distinct portions;
(b) bonding the single crystal semiconducting material substrate with the stiffening material surface to a flexible substrate; and
(c) splitting the single crystal semiconductor substrate along the implanted ion layer, and
(d) removing the portion of the growth substrate, which is on the side of the ion layer away from the flexible substrate, wherein a remaining thin film portion is attached to the flexible substrate.

2: A method according to claim 1, wherein the single crystal semiconductor substrate further comprises a material selected from a group consisting of silicon, germanium, InP, and GaAs and the stiffening material comprises a material selected from the group consisting of silicon dioxide, silicon nitride, silicon, SiC, diamond, spin on glass, metal, polymer, glass frit, and solder.

3: A method according to claim 1, wherein the flexible substrate comprises a material selected from a group consisting of stainless steel foil, plastic, polyimide, polyester, and mylar and the stiffening material comprises a material selected from the group consisting of silicon dioxide, silicon nitride, silicon, SiC, diamond, spin on glass, metal, polymer, glass frit, and solder.

4: A method according to claim 1, further comprising the step of:
depositing a stiffening material layer on the surface of the single crystal substrate devoid of the stiffening material before the implanting step.

5: A method according to claim 4, further comprising the step of:
directing a high pressure nitrogen gas stream or liquid stream towards the side of the single crystal substrate into which a high dose hydrogen ion implantation has been made to split the single crystal substrate.

6: A method according to claim 1, further comprising the step of:
implanting boron at the same selected depth as the implanted hydrogen for lowering the thermal energy required to split the growth substrate.

7: A method according to claim 1, further comprising the step of:
providing an adhesive layer between the bonding surfaces of the thin film functional layer and the flexible substrate before or during step (b) for improving the bonding thereof.

8: The method according to claim 1, wherein the single crystal semiconductor substrate contain etch stop layers, and wherein the peak of the hydrogen ion implant resides at a depth beyond the etch stop layer.

9 (canceled)

10: A method for making a thin film device, said method comprising the steps of:
(a) depositing at least one protective layer on one surface of a large diameter growth substrate;
(b) growing a film layer of thin film functional material on the at least one protective layer, said functional material comprising a material selected from the group consisting of high temperature superconducting (YBCO), ferroelectric, piezoelectric, pyroelectric, high dielectric constant, electro-optic, photoreactive, waveguide, non-linear optical, superconducting, photodetecting, solar cell, wideband gap, shaped memory alloy, and electrically conducting materials;
(c) implanting hydrogen to a selected depth within the growth substrate or within the at least one protective layer to form a hydrogen ion layer so as to divide the material having the growth substrate and the at least one protective layer into distinct portions;
(d) bonding the growth substrate including the at least one protective layer and the thin film layer to a second flexible substrate; and
(e) splitting the material having the growth substrate and the at least one protective layer along the implanted ion layer and removing the portion of the material which is on the side of the ion layer away from the flexible substrate.

11: A method according to claim 10, wherein the growth substrate is comprised of a material selected from a group consisting of silicon, GaAs, quartz, and sapphire.

12: A method according to claim 10, wherein the growth substrate comprising silicon.

13: A method according to claim 10, further comprising the step of:
depositing a stiffening material layer on the surface of the single crystal substrate.

14: A method according to claim 10, further comprising the step of:
directing a high pressure nitrogen gas stream or liquid stream towards the side of the single crystal substrate into which a high dose hydrogen ion implantation has been made to split the single crystal substrate.

15: A method according to claim 10, wherein the growth substrate comprising silicon, wherein the at least one protective layer comprising an oxide layer, an adhesion layer, and a barrier layer; and wherein the method further comprising the steps of;
depositing the oxide layer on the silicon substrate;
depositing the adhesion layer on the oxide layer; and
depositing the barrier layer on the adhesion layer for isolating the thin film layer.

16: A method according to claim 15, wherein the adhesion layer is comprised of titanium, and wherein the barrier layer comprises a material selected from a group consisting of platinum and iridium.

17: A method according to claim 10, the at least one protective layer comprising MgO.

18: A method according to claim 10, wherein the thin film functional material is comprised of a material selected from a group consisting of a single crystal material, a polycrystalline material, and a high temperature sinter ceramic material.

19: A method according to claim 10, wherein the flexible substrate further comprises a material selected from a group consisting of stainless steel foil, plastic, polyinide, polyester, and mylar.

20: A method according to claim 10, further comprising the step of:
annealing the thin film functional material layer for strengthening and tempering the thin film layer.

21: A method according to claim 10, further comprising the step of:
implanting boron at the same selected depth as the implanted hydrogen for lowering the thermal energy required to split the growth substrate.

22: A method according to claim 10, further comprising the step of:
providing an adhesive layer between the bonding surfaces of the thin film functional layer and the flexible substrate before or during step (d) for improving the bonding thereof.

23: A method for making a thin film device, said method comprising the steps of:
(a) growing a film layer of thin film functional material on the surface of a growth substrate, said functional material comprising a material selected from the group consisting of high temperature superconducting (YBCO), ferroelectric, piezoelectric, pyroelectric, high dielectric constant, electro-optic, photoreactive, waveguide, non-linear optical, superconducting, photodetecting, solar cell, wideband gap, shaped memory alloy, and electrically conducting materials;
(b) implanting hydrogen to a selected depth within the growth substrate to form a hydrogen ion layer so as to divide the growth substrate into distinct portions;
(c) bonding the growth substrate and associated material having the thin film layer to a second flexible substrate;
(d) splitting the material having the growth substrate and thin film material along the implanted ion layer and removing the portion of the material which is on the side of the ion layer away from the flexible substrate.

24: A method according to claim 23, further comprising the step of:
depositing a stiffening material layer on the surface of the single crystal substrate.

25: A method according to claim 23, further comprising the steps of:
directing a high pressure nitrogen gas steam or liquid stream towards the side of the single crystal substrate into which a high dose hydrogen ion implantation has been made to split the single crystal substrate.
